(19) United States
(12) Patent Application Publication
(10) Pub. No.: US 2023/0146906 A1
(43) Pub. Date: May 11, 2023

(54) VERTICAL CAVITY SURFACE EMITTING LASER ELEMENT, METHOD OF PRODUCING VERTICAL CAVITY SURFACE EMITTING LASER ELEMENT, AND PHOTOELECTRIC CONVERSION APPARATUS

(71) Applicant: SONY SEMICONDUCTOR SOLUTIONS CORPORATION, KANAGAWA (JP)

(72) Inventors: YOSHIAKI WATANABE, KANAGAWA (JP); YOSHINORI YAMAUCHI, KANAGAWA (JP); HIDEKI KIMURA, KANAGAWA (JP); YUJI MASUI, KUMAMOTO (JP)

(21) Appl. No.: 17/906,729

(22) PCT Filed: Jan. 15, 2021
(86) PCT No.: PCT/JP2021/001194

§ 371 Date: Sep. 19, 2022

(30) Foreign Application Priority Data
Mar. 26, 2020 (JP) 2020-056039

(51) Int. Cl. H01S 5/183

(52) U.S. Cl. CPC H01S 5/18347; H01S 5/18361; H01S 5/18311

(57) ABSTRACT

[Object] To provide a vertical cavity surface emitting laser element having excellent electric responsiveness and high productivity and reliability, a method of producing the vertical cavity surface emitting laser element, and a photoelectric conversion apparatus.

[Solving Means] A vertical cavity surface emitting laser element according to the present technology includes: a semiconductor stacked body. The semiconductor stacked body is a semiconductor stacked body that includes a first mirror having a first conductive type, a second mirror that has a second conductive type and causes optical resonance together with the first mirror, an active layer provided between the first mirror and the second mirror, and a confinement layer that is provided between the first mirror and the second mirror and has a non-oxidized region and an oxidized region, the non-oxidized region being formed of a first material, the oxidized region being provided around the non-oxidized region and being formed of a second material obtained by oxidizing the first material, and has a mesa having an outer peripheral surface from which end surfaces of the active layer and the confinement layer are exposed and an ion implantation region that is a region into which ions have been implanted, is formed to reach a predetermined depth in the active layer and the confinement layer from the outer peripheral surface, and is separated from the non-oxidized region.

### TECHNICAL FIELD

The present technology relates to a vertical cavity surface emitting laser element used for optical communication and the like, a method of producing the vertical cavity surface emitting laser element, and a photoelectric conversion apparatus.

### BACKGROUND ART

A vertical cavity surface emitting laser (VCSEL) element is a kind of semiconductor laser element, and has a structure in which an active layer is sandwiched by a pair of DBRs (Distributed Bragg Reflectors). The pair of DBRs form a resonator and reflect the light generated in the active layer in a direction perpendicular to the layer surface to cause laser oscillation.

A current confinement structure for concentrating a current in a narrow region in the active layer is provided in the vicinity of the active layer. The current confinement structure can be formed by oxidizing a layer to be oxidized from the outer periphery of the VCSEL element formed in a mesa shape (plateau shape) and insulating the outer peripheral region of the layer to be oxidized. As a result, only the central region of the layer to be oxidized has conductivity and it is possible to concentrate a current on the active layer located in the vicinity of the central region.

Further, since the refractive index of an oxidized layer forming the current confinement structure decreases in the process of being oxidized, a region having a low refractive index is formed around a light-emitting region. The distribution of this refractive index in the layer surface has a structure in which light is confined in a portion of the center of the mesa having a high refractive index from a direction along the layer surface and realizes three-dimensionally high light confinement in the active layer together with the above-mentioned resonator structure. When the light confinement is improved, since the ratio of light that receives a stimulated emission gain in the active layer increases, it is possible to make the effective light gain have a high value.

Meanwhile, in order to realize high-speed modulation of the VCSEL element, it is necessary to improve not only the time responsiveness of light but also electric time responsiveness (electrical band) when injecting a current into the active layer. One of the factors that determine the electric time responsiveness is the junction capacitance in p-n junction that occurs in the mesa. In particular, since a high-frequency current passes through also the oxidized layer and flows, the junction capacitance of the outer periphery portion of the mesa via the oxidized layer becomes. Further, since this portion is a region that does not contribute to laser emission at the center of the mesa, it is desired to reduce the junction capacitance of the outer periphery portion of the mesa also in this respect.

For example, Patent Literature 1 discloses a method of implanting ions into an outer periphery portion of a mesa to insulate the outer periphery portion of the mesa. In this example, a DBR on the wafer surface side is etched to immediately above an active layer to form a mesa structure, an implantation mask is attached thereto, and then ion implantation is performed, thereby forming a structure in which a region excluding the active layer immediately below the above-mentioned mesa-shaped DBR is insulated. The insulated layer forms a current confinement layer as it is and defines the current injection diameter of the active layer.

Further, Non-Patent Literature 1 discloses a structure in which an oxidized layer and proton implantation are used in combination to separate a light-emitting region and an ion implantation region from each other. In this structure, in order to achieve reliability, a semiconductor mesa structure is supported by a plurality of semiconductor pillars extending to the outer periphery to form a stabilized structure in which an external force is not easily applied to a mechanically weak oxidized layer portion. Inside this structure, protons are implanted in the range from a p-type mirror of the outer periphery portion of the mesa to the active layer for insulation.

### CITATION LIST

### Patent Literature

Patent Literature 1: Japanese Patent Application Laid-open No. 1993-235473
Non-Patent Literature 1: More VCSELs at Finisar “Proceeding of SPIE—The international Society for Optical Engineering, February 2009, Vol. 7229 722905-1”

### DISCLOSURE OF INVENTION

### Technical Problem

However, in the structure described in Patent Literature 1, since there is no light confinement mechanism in the layer surface direction and the transverse mode of the oscillating laser beam cannot be controlled, it is unsuitable for high-speed modulation and signal transmission because it allows more high-order mode oscillations and causes problems such as contention between unstable modes and noise associated therewith. Further, the position of the laser beam is close to the crystal defect introduced into the ion implantation region when ions are implanted into the active layer, the crystal defect is likely to grow due to energy supply from the active layer having high light intensity at high temperature to the defect, and thus, there is a high possibility that deterioration of the VCSEL element will be promoted.

Further, in the structure described in Non-Patent Literature 1, if it is prepared with insufficient insulation of the outer periphery, part of the injected current flows to the outside of the pillar via the semiconductor pillar (leakage current), and thus, it is necessary to implant protons for insulation in a wide range including not only the outer periphery portion of the mesa but also all the semiconductor pillars and the region outside thereof. Since leakage occurs via the layer with poor insulation if all layers in the implantation range are not evenly insulated also in the depth direction, it is necessary to implant protons evenly also in the depth direction in order to realize this insulated structure.

For this reason, since it is necessary to implant protons over and over while changing the acceleration voltage (while changing the implantation depth) and protons are implanted while scanning the position with an ion beam, it takes several hours to obtain a uniform implantation amount for the entire wafer.

Further, an ion implantation mask (generally formed with a resist) is used on the wafer surface to selectively implant protons into a portion that is desired to be implanted with protons. Since the mask resist after implantation deteriorates and changes in quality due to ion beam irradiation, there are problems that it is difficult to peel off the mask, more means and time are necessary in the case of multi-stage implantation, and it tends to cause a defect in the process depending on the method.

In view of the circumstances as described above, it is an object of the present technology to provide a vertical cavity surface emitting laser element having excellent electric responsiveness and high productivity and reliability, a method of producing the vertical cavity surface emitting laser element, and a photoelectric conversion apparatus.

### Solution to Problem

In order to achieve the above-mentioned object, a vertical cavity surface emitting laser element according to an embodiment of the present technology includes: a semiconductor stacked body.

The semiconductor stacked body is a semiconductor stacked body that includes a first mirror having a first conductive type, a second mirror that has a second conductive type and causes optical resonance together with the first mirror, an active layer provided between the first mirror and the second mirror, and a confinement layer that is provided between the first mirror and the second mirror and has a non-oxidized region and an oxidized region, the non-oxidized region being formed of a conductive material, the oxidized region being provided around the non-oxidized region and being formed of an insulating material obtained by oxidizing the conductive material, and has a mesa having an outer peripheral surface from which end surfaces of the active layer and the confinement layer are exposed and an ion implantation region that is a region into which ions have been implanted, is formed to reach a predetermined depth in the active layer and the confinement layer from the outer peripheral surface, and is separated from the non-oxidized region.

In accordance with this configuration, by providing an ion implantation region from an outer peripheral surface of a mesa to a predetermined depth, it is possible to prevent a current from transmitting in the outer peripheral region of the mesa, reduce the junction capacitance in the outer peripheral region of the mesa, and improve the electrical band of the vertical cavity surface emitting laser element.

The mesa may be formed by partial removable of the semiconductor stacked body, and

the ion implantation region may be exposed on a removal surface formed by the partial removable of the semiconductor stacked body.

The vertical cavity surface emitting laser element may further include an insulator that is provided around the mesa and covers the removal surface.

The ion implantation region may have one peak of concentration distribution of an ion species of the ions in a direction perpendicular to a layer surface direction.

The ion species may be H, and

an implantation amount of the ion species may be 5×10¹⁴ ions/cm² or more.

The ion species may be C, B, O, Ar, Al, Ga, or As, and an implantation amount of the ion species may be 5×10¹³ ions/cm² or more.

The mesa may have a surface parallel to a layer surface direction,

the vertical cavity surface emitting laser element may further include an electrode formed on the surface, in which

the semiconductor stacked body may further have an impurity diffusion region formed to reach a predetermined depth from the outer peripheral surface between the electrode and the ion implantation region, an impurity being diffused in the impurity diffusion region.

The impurity diffusion region may be a region in which the impurity is thermally diffused.

The impurity diffusion region may be provided in a range that overlaps with the ion implantation region when the mesa is viewed from a direction perpendicular to the layer surface direction.

The impurity diffusion region may have a concentration of the impurity of 1×10¹⁷/cm³ or more.

The impurity diffusion region may be provided in the first mirror,

the first conductive type may be a p-type, and

the impurity may be C, Zn, or Mg.

The impurity diffusion region may be provided in the first mirror,

the first conductive type may be an n-type, and

the impurity may be Si, S, or Se.

In order to achieve the above-mentioned object, a method of producing a vertical cavity surface emitting laser element according to an embodiment of the present technology includes: forming a semiconductor stacked body that includes a first mirror having a first conductive type, a second mirror that has a second conductive type and causes optical resonance together with the first mirror, an active layer provided between the first mirror and the second mirror, and a confinement layer provided between the first mirror and the second mirror.

In the semiconductor stacked body, ions are implanted from a direction perpendicular to a layer surface direction excluding a non-implantation region to form an ion implantation region.

The semiconductor stacked body is etched to form a mesa that has the non-implantation region and an outer peripheral surface from which end surfaces of the active layer and the confinement layer are exposed, the ion implantation region being distributed from the outer peripheral surface to a first depth in the active layer and the confinement layer.

The confinement layer is oxidized from the outer peripheral surface to form an oxidized region from the outer peripheral surface to a second depth deeper than the first depth in the confinement layer.

The method of producing a vertical cavity surface emitting laser element may further include a step of diffusing an impurity in the semiconductor stacked body to form an impurity diffusion region.

The step of forming an impurity diffusion region may be performed after the step of forming an ion implantation region and before the step of forming a mesa, and the impurity may be diffused in a region through which the ions have passed in the step of forming an ion implantation region.

The step of forming an impurity diffusion region may include diffusing the impurity by thermal diffusion.

In order to achieve the above-mentioned object, a photoelectric conversion apparatus according to an embodiment of the present technology includes: a vertical cavity surface emitting laser element.

The vertical cavity surface emitting laser element includes a semiconductor stacked body that includes a first mirror having a first conductive type, a second mirror that has a second conductive type and causes optical resonance together with the first mirror, an active layer provided between the first mirror and the second mirror, and a confinement layer that is provided between the first mirror and the second mirror and has a non-oxidized region and an oxidized region, the non-oxidized region being formed of a conductive material, the oxidized region being provided around the non-oxidized region and being formed of an insulating material obtained by oxidizing the conductive material, and has a mesa having an outer peripheral surface from which end surfaces of the active layer and the confinement layer are exposed and an ion implantation region that is a region into which ions have been implanted, is formed to reach a predetermined depth in the active layer and the confinement layer from the outer peripheral surface, and is separated from the non-oxidized region.

The mesa may have a surface parallel to a layer surface direction, the vertical cavity surface emitting laser element may further include an electrode formed on the surface, in which the semiconductor stacked body may further have an impurity diffusion region formed to reach a predetermined depth from the outer peripheral surface between the electrode and the ion implantation region, an impurity being diffused in the impurity diffusion region.

### BRIEF DESCRIPTION OF DRAWINGS

FIG. 1 is a cross-sectional view of a vertical cavity surface emitting laser (VCSEL) element according to a first embodiment of the present technology.

FIG. 2 is a plan view of the VCSEL element.

FIG. 3 is a cross-sectional view of a semiconductor stacked body included in the VCSEL element.

FIG. 4 is a plan view of a confinement layer included in the VCSEL element.

FIG. 5 is a plan view of a mesa formed in the semiconductor stacked body included in the VCSEL element.

FIG. 6 is a cross-sectional view of the VCSEL element.

FIG. 7 is a cross-sectional view of the semiconductor stacked body included in the VCSEL element.

FIG. 8 is a plan view of the mesa formed in the semiconductor stacked body included in the VCSEL element.

FIG. 9 is a plan view of the mesa formed in the semiconductor stacked body included in the VCSEL element.

FIG. 10 is a schematic diagram showing an operation of the VCSEL element.

FIG. 11 is a schematic diagram showing a method of producing the VCSEL element.

FIG. 12 is a schematic diagram showing the method of producing the VCSEL element.

FIG. 13 is a schematic diagram showing the method of producing the VCSEL element.

FIG. 14 is a cross-sectional view of a vertical cavity surface emitting laser (VCSEL) element according to a second embodiment of the present technology.

FIG. 15 is a plan view of the VCSEL element.

FIG. 16 is a cross-sectional view of the VCSEL element.

FIG. 17 is a cross-sectional view of a semiconductor stacked body included in the VCSEL element.

FIG. 18 is a plan view of a mesa formed in the semiconductor stacked body included in the VCSEL element.

FIG. 19 is a schematic diagram showing the distribution of an ion implantation region and an impurity diffusion region in the VCSEL element.

FIG. 20 is a schematic diagram showing the distribution of the ion implantation region and the impurity diffusion region in the VCSEL element.

FIG. 21 is a schematic diagram showing an operation of the VCSEL element.

FIG. 22 is a schematic diagram showing a method of producing the VCSEL element.

FIG. 23 is a schematic diagram showing the method of producing the VCSEL element.

FIG. 24 is a schematic diagram showing the method of producing the VCSEL element.

FIG. 25 is a schematic diagram showing the effects of the impurity diffusion region in the VCSEL element.

FIG. 26 is a schematic diagram showing the effects of the impurity diffusion region in the VCSEL element.

### MODE(S) FOR CARRYING OUT THE INVENTION

### First Embodiment

A vertical cavity surface emitting laser (VCSEL) element according to a first embodiment of the present technology will be described.

[Structure of VCSEL Element]

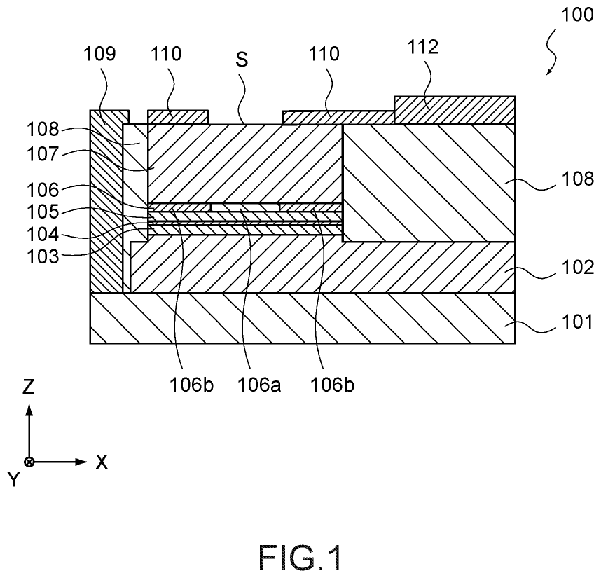

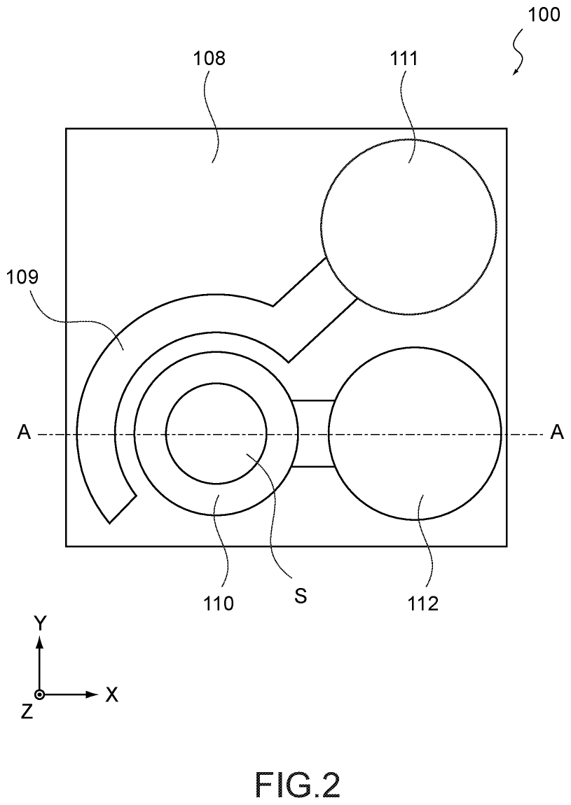

FIG. 1 is a cross-sectional view of a VCSEL element 100 according to this embodiment, and FIG. 2 is a plan view of the VCSEL element 100. FIG. 1 is a cross-sectional view taken along the line A-A in FIG. 2. Note that in the drawings of the present disclosure, the light emission direction of the VCSEL element 100 is defined as a Z direction, one direction orthogonal to the Z direction is defined as an X direction, and a direction orthogonal to the X direction and the Z direction is defined as a Y direction. Further, in the following description, the oscillation wavelength of the VCSEL element 100 is defined as λ.

As shown in FIG. 1 and FIG. 2, the VCSEL element 100 includes a substrate 101, an n-type mirror 102, an n-side spacer layer 103, an active layer 104, a p-side spacer layer 105, a confinement layer 106, a p-type mirror 107, an insulator 108, an n-electrode 109, a p-electrode 110, an n-electrode pad 111, and a p-electrode pad 112.

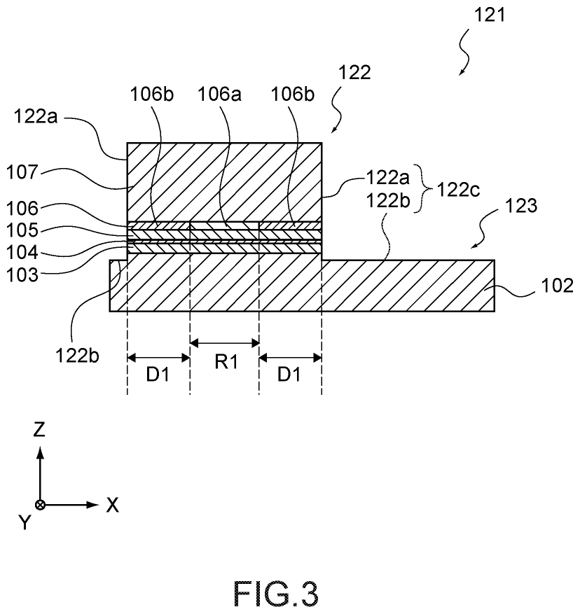

A stacked body obtained by stacking the n-type mirror 102, the n-side spacer layer 103, the active layer 104, the p-side spacer layer 105, the confinement layer 106, and the p-type mirror 107 is defined as a semiconductor stacked body 121. FIG. 3 is a cross-sectional view of the semiconductor stacked body 121. As shown in the figure, the respective layers of the semiconductor stacked body 121 are stacked such that the layer surface direction is along the X-Y plane.

The substrate 101 supports the respective layers of the VCSEL element 100. The substrate 101 can include, for example, an n-GaAs substrate but may be formed of another material.

The n-type mirror 102 is formed of an n-type semiconductor material, is provided on the substrate 101, and reflects light having a wavelength A. The n-type mirror 102 functions as a DBR (Distributed Bragg Reflector) and constitutes an optical resonator for laser oscillation together with the p-type mirror 107. The n-type mirror 102 can include, for example, a plurality of layers obtained by alternately stacking two layers of n-AlGaAs having different composition ratios.

The n-side spacer layer 103 is stacked on the n-type mirror 102 to adjust the interval between the n-type mirror 102 and the p-type mirror 107 to λ. The n-side spacer layer 103 is formed of an n-type semiconductor material or a non-doped semiconductor material and can be formed of, for example, n-AlGaAs.

The active layer 104 is provided on the n-side spacer layer 103 and emits and amplifies spontaneously emitted light. The active layer 104 can include a plurality of layers obtained by alternately stacking a quantum well layer and a barrier layer. The quantum well layer can be formed of, for example, InGaAs and the barrier layer can be formed of, for example, InGaAs having a composition ratio different from that of the quantum well layer.

The p-side spacer layer 105 is stacked on the active layer 104 to adjust the interval between the n-type mirror 102 and the p-type mirror 107 to A. The p-side spacer layer 105 is formed of a p-type semiconductor material or a non-doped semiconductor material and can be formed of, for example, p-AlGaAs.

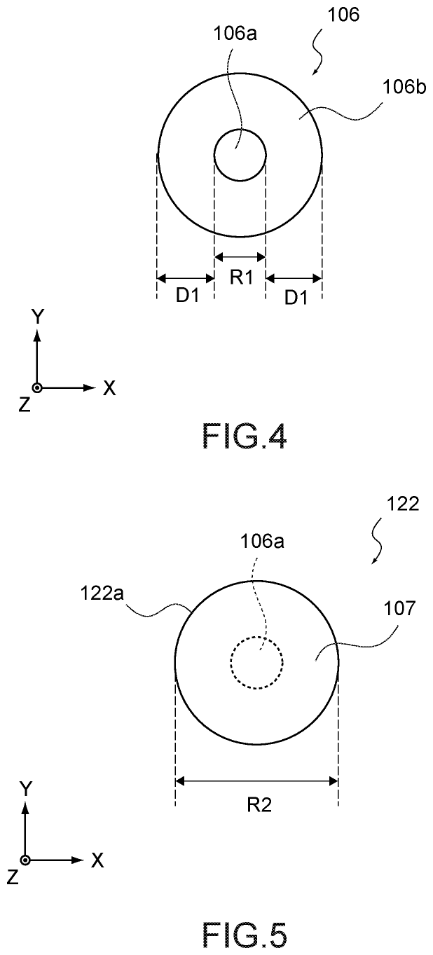

The confinement layer 106 is provided on the p-side spacer layer 105 to impart a confinement action to a current and confine light in the X-Y direction. FIG. 4 is a plan view of the confinement layer 106. As shown in the figure, the confinement layer 106 includes a non-oxidized region 106a and an oxidized region 106b. The non-oxidized region 106a is provided at the center of the confinement layer 106 and has a circular shape. The oxidized region 106b is provided around the non-oxidized region 106a. As shown in FIG. 3 and FIG. 4, the inner diameter of the oxidized region 106b is defined as an inner diameter R1.

The non-oxidized region 106a is formed of a conductive material and the oxidized region 106b is formed of an insulating material obtained by oxidizing the material of the non-oxidized region 106a. For example, the non-oxidized region 106a can be formed of AlAs and the oxidized region 106b can be formed of an AlAs oxide. The oxidized region 106b becomes insulating due to oxidization and the conductivity thereof is greatly reduced as compared with the non-oxidized region 106a, thereby causing a current confinement action. Further, in the oxidized region 106b, the refractive index is reduced by oxidization as compared with the non-oxidized region 106a, thereby causing a light confinement effect in the X-Y direction.

The p-type mirror 107 is formed of a p-type semiconductor material, is provided on the confinement layer 106, and reflects light having the wavelength λ. The p-type mirror 107 functions as a DBR and constitutes an optical resonator for laser oscillation together with the n-type mirror 102. The p-type mirror 107 can include, for example, a plurality of layers obtained by stacking two layers of p-AlGaAs having different composition ratios.

The semiconductor stacked body 121 has a mesa (plateau shape) structure. Specifically, as shown in FIG. 3, the p-type mirror 107, the confinement layer 106, the p-side spacer layer 105, the active layer 104, the n-side spacer layer 103, and the n-type mirror 102 are partially removed to form a pillar-shaped mesa 122 including these layers. A recessed portion formed by this removal is defined as a recessed portion 123.

FIG. 5 is a plan view showing the mesa 122. As shown in the figure, the mesa 122 has a circular shape as viewed from the Z direction and can have a cylindrical shape. The outer diameter of the mesa 122 is defined as an outer diameter R2. As shown in FIG. 3 and FIG. 5, the outer peripheral surface of the mesa 122 is defined as an outer peripheral surface 122a.

The outer peripheral surface 122a is a surface formed by the above-mentioned removal, and end surfaces of the p-type mirror 107, the confinement layer 106, the p-side spacer layer 105, the active layer 104, the n-side spacer layer 103, and the n-type mirror 102 are exposed on the outer peripheral surface 122a. Further, the above-mentioned removal forms a surface parallel to the layer surface direction (X-Y plane), which is continuous to the outer peripheral surface 122a, on the n-type mirror 102. Hereinafter, this surface will be referred to as the non-outer peripheral surface 122b. Further, the surface that is formed by the above-mentioned removal and includes the outer peripheral surface 122a and the non-outer peripheral surface 122b will be referred to as the removal surface 122c.

In the above-mentioned confinement layer 106, the oxidized region 106b is formed to reach a certain depth from the outer peripheral surface 122a. In FIG. 3 and FIG. 4, the depth of the oxidized region 106b from the outer peripheral surface 122a is shown as a depth D1.

The insulator 108 is formed of an insulating material, is provided in the recessed portion 123 (see FIG. 3), and covers the removal surface 122c. The insulator 108 protects the removal surface 122c, suppresses unnecessary junction capacitance, and supports the n-electrode pad 111 and the p-electrode pad 112. The insulator 108 can be formed of a resin such as polyimide and BCB (Benzocyclobutene), an inorganic matter such as SiO₂ and SiN, or the like.

The n-electrode 109 penetrates the insulator 108, is electrically connected to the substrate 101, and functions as an n-side electrode of the VCSEL element 100. The n-electrode 109 is formed of an arbitrary conductive material. The p-electrode 110 is formed on the p-type mirror 107, is electrically connected to the p-type mirror 107, and functions as a p-side electrode of the VCSEL element 100. The p-electrode 110 is formed of an arbitrary conductive material and is formed in an annular shape on the p-type mirror 107 as shown in FIG. 2.

The n-electrode pad 111 is provided on the insulator 108 and is electrically connected to the n-electrode 109. The n-electrode pad 111 is formed of an arbitrary conductive material. The p-electrode pad 112 is provided on the insulator 108 and is electrically connected to the p-electrode 110. The p-electrode pad 112 is formed of an arbitrary conductive material.

Here, of the surface of the p-type mirror 107, a region surrounded by the p-electrode 110 is a light-emitting surface from which a laser beam is emitted in the VCSEL element 100. In the drawings, the light-emitting surface is shown as a light-emitting surface S.

[Regarding Ion Implantation Region]

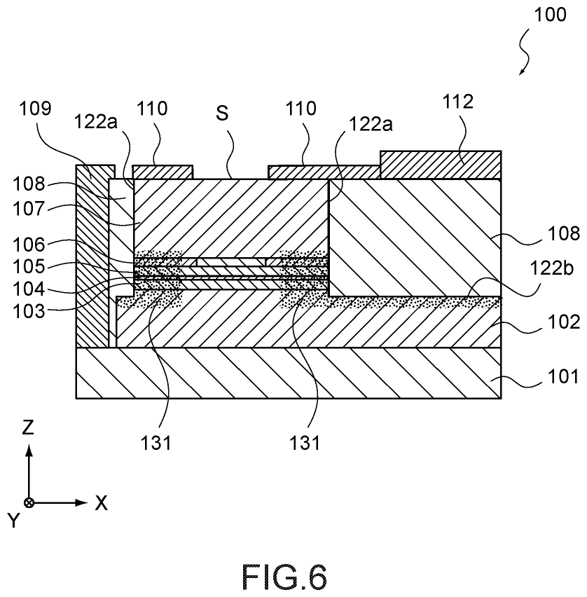

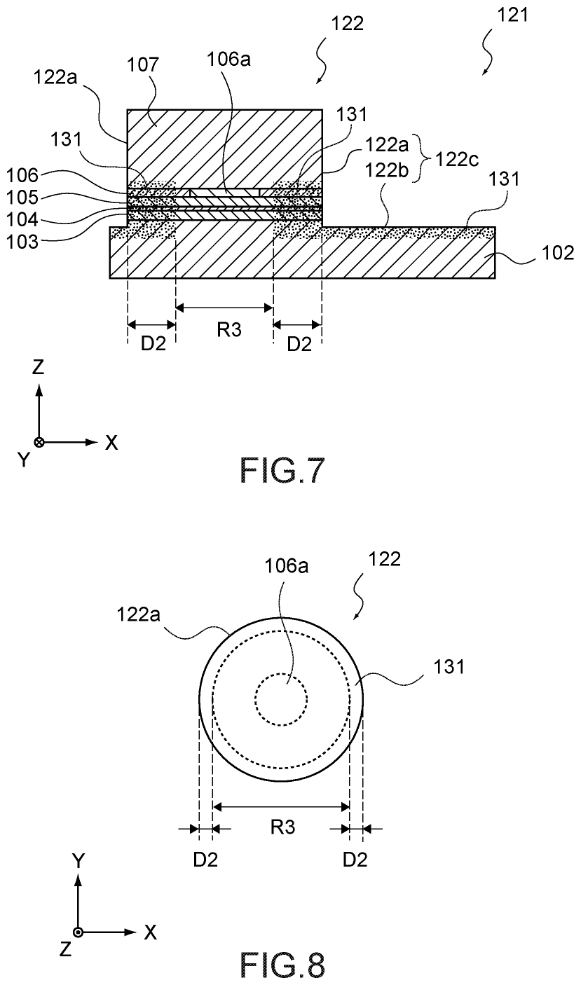

In the VCSEL element 100, an ion implantation region is provided in the semiconductor stacked body 121, ions being implanted into the ion implantation region. FIG. 6 is a cross-sectional view of the VCSEL element 100 showing an ion implantation region 131 and is a cross-sectional view taken along the line A-A shown in FIG. 2. FIG. 7 is a cross-sectional view of the semiconductor stacked body 121 showing the ion implantation region 131 and is a diagram showing a partial configuration of FIG. 6. In FIG. 6 and FIG. 7, the ion implantation region 131 is a region indicated by dots. FIG. 8 is a plan view of the mesa 122 showing the ion implantation region 131.

The ion implantation region 131 is a region insulated by implanting ions into the material of the semiconductor stacked body 121. As shown in FIG. 6 to FIG. 8, the ion implantation region 131 is formed to reach a predetermined depth of the n-side spacer layer 103, the active layer 104, the p-side spacer layer 105, and the confinement layer 106 from the outer peripheral surface 122a of the mesa 122, i.e., formed in an annular shape on the outer periphery portion of these layers. In FIG. 7 and FIG. 8, a depth from the outer peripheral surface 122a of the ion implantation region 131 is shown as a depth D2.

The depth D2 is a depth shallower than the depth D1 (see FIG. 3) that is the depth of the oxidized region 106b from the outer peripheral surface 122a, and does not reach the non-oxidized region 106a. For this reason, the ion implantation region 131 provided in the confinement layer 106 is separated from the non-oxidized region 106a. In FIG. 7 and FIG. 8, the inner diameter of the ion implantation region 131 is shown as an inner diameter R3.

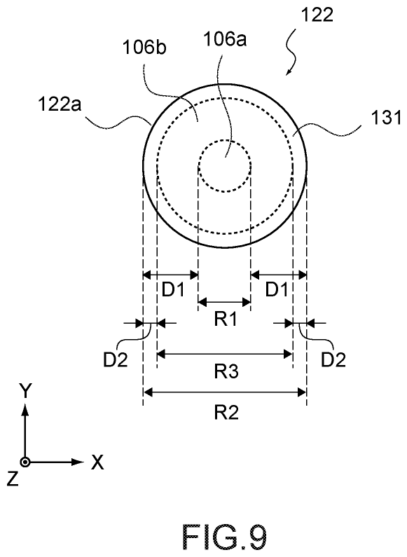

FIG. 9 is a schematic diagram showing the inner diameter R1 of the oxidized region 106b, the outer diameter R2 of the mesa 122, and the inner diameter R3 of the ion implantation region 131. As shown in the figure, the inner diameter R3 is a diameter that is larger than the inner diameter R1 and smaller than the outer diameter R2.

Further, the ion implantation region 131 is formed also in part of the n-type mirror 102 on the side of the active layer 104 and in part of the p-type mirror 107 on the side of the active layer 104. As shown in FIG. 7, the ion implantation region 131 can be exposed on the non-outer peripheral surface 122b and can be formed to reach a certain depth from the non-outer peripheral surface 122b.

The ion species of ions to be implanted into the ion implantation region 131 can be H, C, B, O, Ar, Al, Ga, or As. Of these, an H ion (proton) is suitable because it has the smallest atomic radius and is easy to implant deeply. The implantation amount (dose amount) of the ion is suitably 5×10¹⁴ ions/cm² or more in the case of H, and is suitably 5×10¹³ ions/cm² or more in the case of another ion species.

Here, the concentration distribution of the ion species in the ion implantation region 131 differs depending on the number of ion implantation stages described below. In the case where the ion implantation region 131 is formed by one-stage implantation of ions, the concentration distribution of the ion species in the direction (Z direction) perpendicular to a layer surface direction has only one peak. Meanwhile, in the case where the ion implantation region 131 is formed by multi-stage implantation of ions, the concentration distribution of the ion species in the direction (Z direction) perpendicular to a layer surface direction has many peaks.

Note that the ion implantation region 131 does not need to be provided in all the respective layers and only needs to be provided in at least the active layer 104 and the confinement layer 106.

The VCSEL element 100 has the configuration as described above. Note that in the VCSEL element 100, the n-type and the p-type may be reversed. Further, the VCSEL element 100 described above may include another layer in addition to the respective layers described above.

[Operation of VCSEL Element]

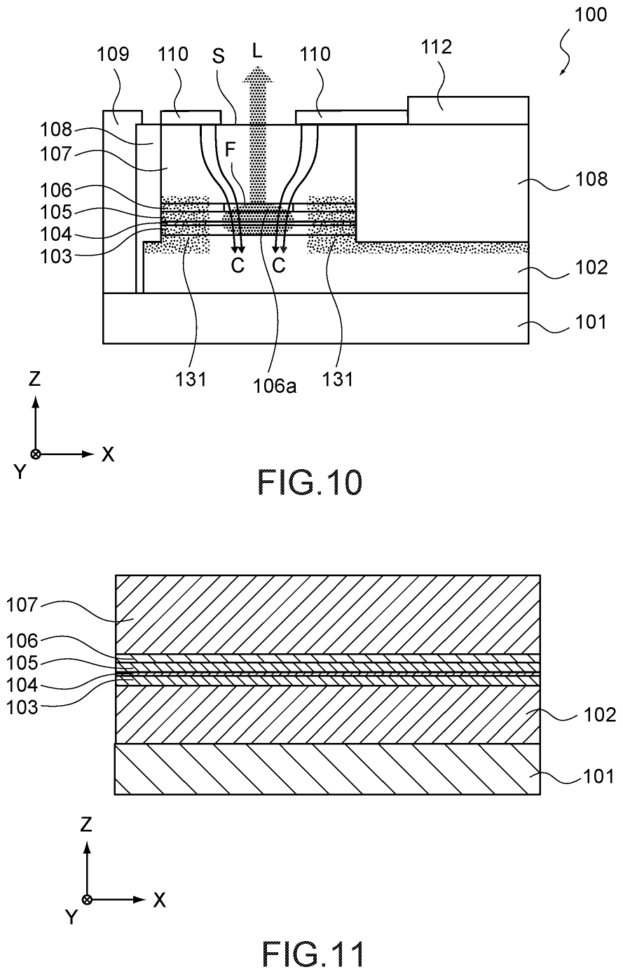

An operation of the VCSEL element 100 will be described. FIG. 10 is a schematic diagram showing an operation of the VCSEL element 100. When a voltage is applied between the n-electrode 109 and the p-electrode 110, a current flows between the n-electrode 109 and the p-electrode 110. The current is subjected to a current confinement action by the confinement layer 106 and is injected to the non-oxidized region 106a as shown by arrows C in FIG. 9.

This injected current causes spontaneously emitted light F in a region close to the non-oxidized region 106a in the active layer 104. The spontaneously emitted light F travels in the stacking direction of the VCSEL element 100 and is reflected by the n-type mirror 102 and the p-type mirror 107. At this time, the spontaneously emitted light F receives a light confinement effect in the layer surface direction (X-Y direction) by the oxidized region 106b having a small refractive index.

Since the n-type mirror 102 and the p-type mirror 107 are each configured to reflect light having the oscillation wavelength λ, the component having the oscillation wavelength λ, of the spontaneously emitted light, forms a standing wave between the n-type mirror 102 and the p-type mirror 107 and is amplified by the active layer 104. When the injected current exceeds a threshold value, laser oscillation of light forming a standing wave occurs, a laser beam L passes through the p-type mirror 107 and is emitted from a light-emitting surface S.

Here, in the VCSEL element 100, the insulated ion implantation region 131 is provided in the outer peripheral region of the active layer 104 and the like. Although a current is subjected to a confinement action by the confinement layer 106 as described above and is concentrated in the non-oxidized region 106a, part of the current passes through the oxidized region 106b. In particular, when the frequency of the current rises with the increase in the electrical band, a current passing through the oxidized region 106b increases and the junction capacitance in the outer peripheral region of the mesa 122 increases, which makes it difficult to increase the band.

Here, in the VCSEL element 100, by providing the ion implantation region 131, it is possible to prevent a current from passing through the outer peripheral region of the mesa 122, reduce the junction capacitance in the outer peripheral region of the mesa 122, and improve the electrical band of the VCSEL element 100.

Further, since the inner diameter R3 of the ion implantation region 131 is larger than the inner diameter R1 of the oxidized region 106b (see FIG. 9), it is possible to define an insulation region (capacitance reduction region) by the inner diameter R3 while defining a light-emitting region by the inner diameter R1. That is, in the VCSEL element 100, since it is possible to individually define a light-emitting region and an insulation region, light-emitting mode design of a laser is easy.

[Method of Producing VCSEL Element]

A method of producing the VCSEL element 100 will be described. FIG. 11 to FIG. 13 are each a method of producing the VCSEL element 100.

As shown in FIG. 11, the n-type mirror 102, the n-side spacer layer 103, the active layer 104, the p-side spacer layer 105, the confinement layer 106, and the p-type mirror 107 are stacked on the substrate 101 in this order. These layers can be stacked by epitaxial growth by MOCVD (metal organic chemical vapor deposition).

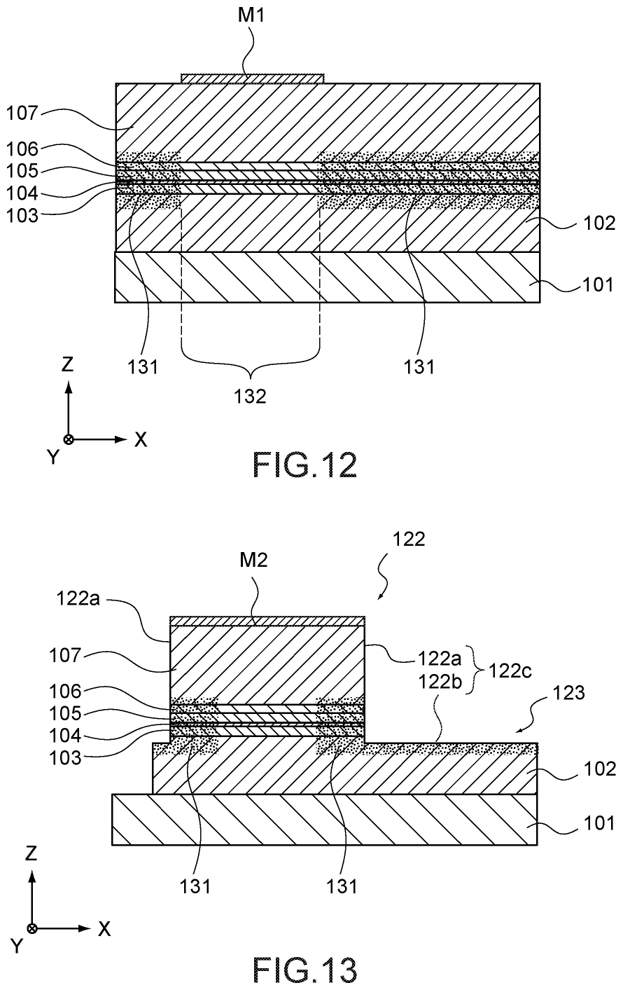

Next, as shown in FIG. 12, a mask M1 using a resist or the like is formed on the p-type mirror 107. Further, ions are implanted from above the mask M1 using an ion implanter to form the ion implantation region 131. A region into which ions have not been implanted due to the mask M1 is defined as a non-implantation region 132. The depth of ion implantation in the ion implantation region 131 is within a range in which at least the active layer 104 and the confinement layer 106 are included in the ion implantation region 131 in the depth direction (Z direction).

The range of the ion implantation region 131 in the depth direction (Z direction) can be adjusted by the acceleration voltage at the time of ion implantation, and the ion concentration can be adjusted by the dose amount at the time of ion implantation. In the case where the ion implantation region 131 can be implanted in a necessary range by one time of ion implantation, ions are implanted by one-stage implantation with a constant acceleration voltage. In the case where the ion implantation region 131 cannot be formed in a necessary range by one time of ion implantation, ions are implanted by multi-stage ion implantation.

After that, the mask M1 is peeled off, and a mask M2 is formed on the p-type mirror 107 as shown in FIG. 13. Further, the p-type mirror 107, the confinement layer 106, the p-side spacer layer 105, the active layer 104, the n-side spacer layer 103, and the n-type mirror 102 are removed by etching using the mask M2. The etching can be, for example, dry etching.

By this etching, the pillar-shaped mesa 122 having the non-implantation region 132 is formed, and the removal surface 122c including the outer peripheral surface 122a and the non-outer peripheral surface 122b is formed. End surfaces of the respective layers including the active layer 104 and the confinement layer 106 are exposed on the outer peripheral surface 122a. At this time, the depth D2 (see FIG. 7) of the ion implantation region 131 from the outer peripheral surface 122a can be defined by the size of the mask M2. Further, the etching depth (Z direction) is suitably within the depth range of the ion implantation region 131 in the n-type mirror 102. As a result, the ion implantation region 131 provided in the n-type mirror 102 is exposed on the non-outer peripheral surface 122b.

Further, this stacked body is heated in water vapor to oxidize the confinement layer 106 from the outer periphery side. As a result, the oxidized region 106b is formed in the outer periphery portion of the confinement layer 106, and the non-oxidized region 106a is formed on the central part of the confinement layer 106. At this time, the oxidization condition is adjusted such that the depth D1 of the oxidized region 106b from the outer peripheral surface 122a is deeper than the depth D2 (see FIG. 9). As a result, the inner diameter R1 of the oxidized region 106b is smaller than the inner diameter R3 of the ion implantation region 131, and the non-oxidized region 106a is formed to be separated from the ion implantation region 131.

After that, the insulator 108 is embedded in the recessed portion 123, and the n-electrode 109, the p-electrode 110, the n-electrode pad 111, and the p-electrode pad 112 are formed, whereby the VCSEL element 100 can be produced.

In this production method, since the ion implantation region 131 can be formed by adding a several-stage step (mask formation/ion implantation/mask peeling) necessary for ion implantation, it is substantially unnecessary to change the production process. Further, since the number of states for implanting ions is small, it is possible to significantly reduce the process time.

Further, since the change in quality of the mask M1 due to ion implantation can be minimized, even in the case where the mask M1 that is very thick (thickness of approximately 5 μm or more) and difficult to peel off is used, the mask M1 can be easily peeled off even by immersion in a peeling liquid and it is possible to avoid the remaining of the mask M1 and an additional peeling step associated therewith.

Further, in the removal surface 122c generated by the etching step when forming the mesa 122, the vicinity of the active layer 104 and the non-outer peripheral surface 122b, of the outer peripheral surface 122a, form the ion implantation region 131. Here, it is known that the processing surface by dry etching tends to form a damaged layer in the vicinity of the surface thereof due to the problem of adsorption of etching gas molecules and physical damage received during processing.

In the VCSEL element 100, in the case where also the active layer 104 is etched off by dry etching, there is a possibility that a damaged layer is generated by dry etching also on the end surface of the active layer 104 in the outer peripheral surface 122a. This damaged layer can cause a decrease in reliability due to the influence of carriers spreading in the active layer 104 when the VCSEL element 100 is driven.

However, in the VCSEL element 100, since the ion implantation region 131 is formed in the vicinity of the end surface of the active layer 104 and insulated, carriers are shielded from the damaged layer, which prevents the reliability from decreasing. Further, although there is a possibility that a damaged layer is generated due to dry etching also in the non-outer peripheral surface 122b, it is possible to stabilize the etching processing surface by insulating the non-outer peripheral surface 122b by the ion implantation region 131.

[Effects of VCSEL Element]

In the VCSEL element 100, as described above, the refractive index decreases due to oxidization in the oxidized region 106b formed in the confinement layer 106, and a region having a low refractive index is formed around the light-emitting portion. As a result, three-dimensionally high light confinement in the active layer 104 is realized together with the optical resonator structure by the n-type mirror 102 and the p-type mirror 107. When the light confinement is improved, since the ratio of light that receives a stimulated emission gain in the active layer 104 increases and the effective light gain has a high value, it is possible to make the time responsiveness of light high.

Further, in the VCSEL element 100, by providing the ion implantation region 131, it is possible to prevent a current from passing through the outer peripheral region of the mesa 122 and reduce the junction capacitance in the outer peripheral region of the mesa 122. As a result, it is possible to improve the electric time responsiveness of the VCSEL element 100. As described above, in the VCSEL element 100, it is possible to improve both the time responsiveness of light and electric time responsiveness and realize high-speed modulation.

In addition, since it is possible to individually define a capacitance reduction region by the distribution of the ion implantation region 131 and a light-emitting region by the distribution of the non-oxidized region 106a, light-emitting mode design of a laser is easy. Since it is possible to separate a crystal defect and a light-emitting region by etching from each other, it is also possible to achieve high reliability.

Also in terms of productivity, the ion implantation region 131 can be formed by adding a several-stage step necessary for ion implantation. Therefore, the VCSEL element 100 has high productivity with substantially no need to change the production process.

Further, even when compared with the structure (see Non-Patent Literature 1) in which pillars are provided around a semiconductor mesa to separate a light-emitting region and an ion implantation region from each other, since the mesa 122 is embedded with the insulator 108 having a dielectric constant lower than that of a semiconductor instead of pillars, there is no problem of stray capacitance of pillars and the capacitance reduction effect by ion implantation in the outer periphery portion of the mesa 122 can be maximized, thereby making it possible to realize a higher electrical band (e.g., 30 GHz or more).

Further, since there is no pillar, an injected current does not become a leakage current and the current is injected into the ion implantation region 131 and the non-oxidized region 106a without loss, so that deterioration (noise etc.) of transmission signals and reliability problems due to the leakage current are less likely to occur.

[Regarding Photoelectric Conversion Apparatus]

The VCSEL element 100 can be used as a light-emitting element in a photoelectric conversion apparatus for communication. Since the VCSEL element 100 is capable of performing high-speed modulation and has high reliability as described above, it is suitable for use in ultra-high-speed optical communication such as a communication speed of 50 Gbps.

### Second Embodiment

A vertical cavity surface emitting laser (VCSEL) element according to a second embodiment of the present technology will be described. The VCSEL element according to this embodiment has the same configuration as that of the VCSEL element 100 according to the first embodiment except that an impurity diffusion region is provided. Hereinafter, in the configuration of the VCSEL element according to the second embodiment, the same configuration as that of the VCSEL element 100 according to the first embodiment will be denoted by the same reference symbols as those of the VCSEL element 100 and description thereof will be omitted.

[Structure of VCSEL Element]

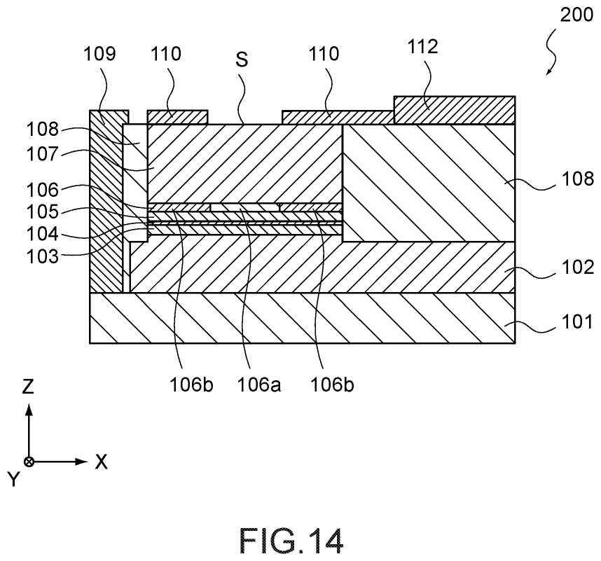

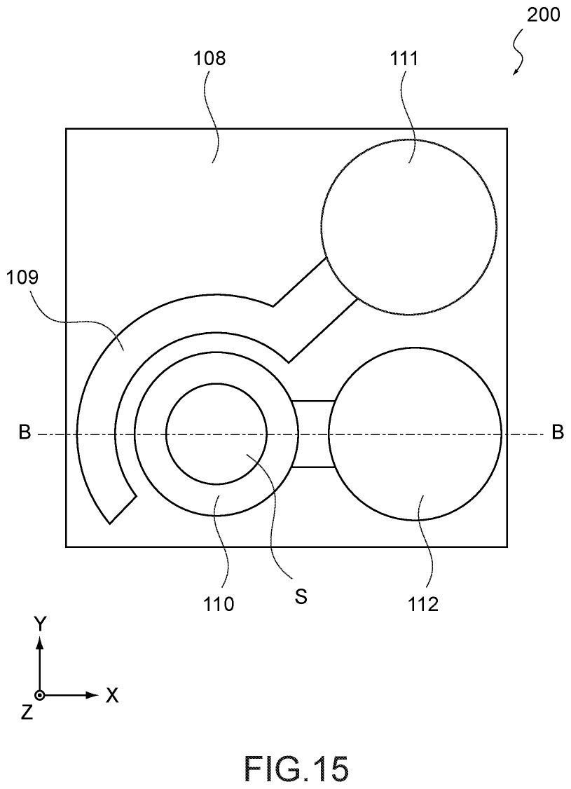

FIG. 14 is a cross-sectional view of a VCSEL element 200 according to this embodiment, and FIG. 15 is a plan view of the VCSEL element 100. FIG. 14 is a cross-sectional view taken along the line B-B in FIG. 15. Note that in the following figures, the light emission direction of the VCSEL element 200 is defined as the Z direction, one direction orthogonal to the Z direction is defined as the X direction, and a direction orthogonal to the X direction and the Z direction is defined as the Y direction. Further, in the following description, the oscillation wavelength of the VCSEL element 200 is defined as A.

As shown in FIG. 14 and FIG. 15, the VCSEL element 200 includes the substrate 101, the n-type mirror 102, the n-side spacer layer 103, the active layer 104, the p-side spacer layer 105, the confinement layer 106, the p-type mirror 107, the insulator 108, the n-electrode 109, the p-electrode 110, the n-electrode pad 111, and the p-electrode pad 112.

These configurations are the same as those in the first embodiment, and the confinement layer 106 includes the non-oxidized region 106a and the oxidized region 106b. The non-oxidized region 106a has the inner diameter R1, and the depth of the oxidized region 106b from the outer peripheral surface 122a is defined as the depth D1 (see FIG. 3 and FIG. 4).

Further, also in this embodiment, a stacked body obtained by stacking the n-type mirror 102, the n-side spacer layer 103, the active layer 104, the p-side spacer layer 105, the confinement layer 106, and the p-type mirror 107 is defined as the semiconductor stacked body 121 (see FIG. 3). Further, of the surface of the p-type mirror 107, a region surrounded by the p-electrode 110 is the light-emitting surface S from which a laser beam is emitted in the VCSEL element 200.

[Regarding Ion Implantation Region and Impurity Diffusion Region]

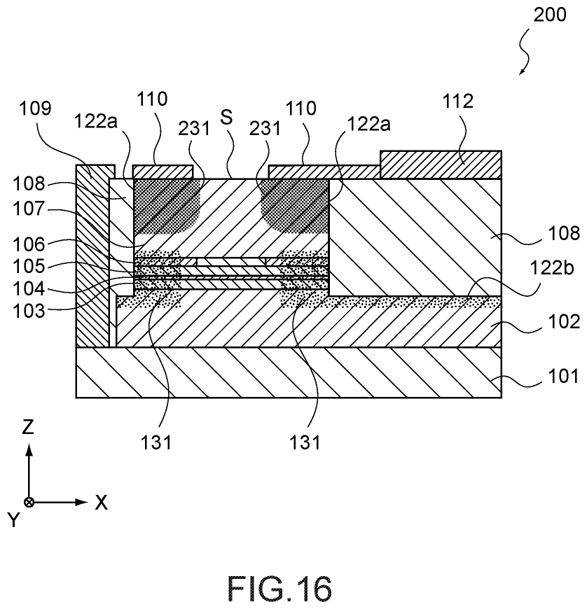

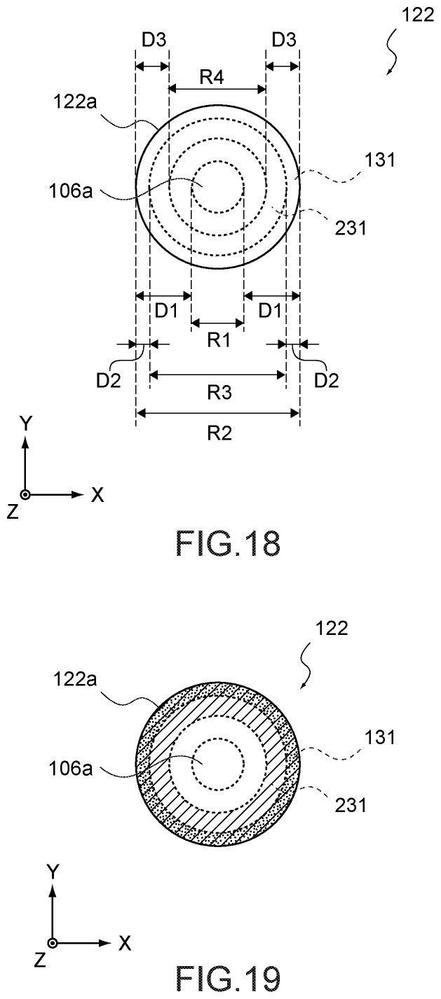

In the VCSEL element 200, an ion implantation region and an impurity diffusion region are provided in the semiconductor stacked body 121, ions being implanted into the ion implantation region, an impurity being diffused in the impurity diffusion region. FIG. 16 is a cross-sectional view of the VCSEL element 200 showing the ion implantation region 131 and an impurity diffusion region 231 and is a cross-sectional view taken along the line B-B shown in FIG. 15. FIG. 16 is a cross-sectional view of the semiconductor stacked body 121 showing the ion implantation region 131 and the impurity diffusion region 231 and is a diagram showing a partial configuration of FIG. 16. FIG. 18 is a plan view of the mesa 122 showing the ion implantation region 131 and the impurity diffusion region 231.

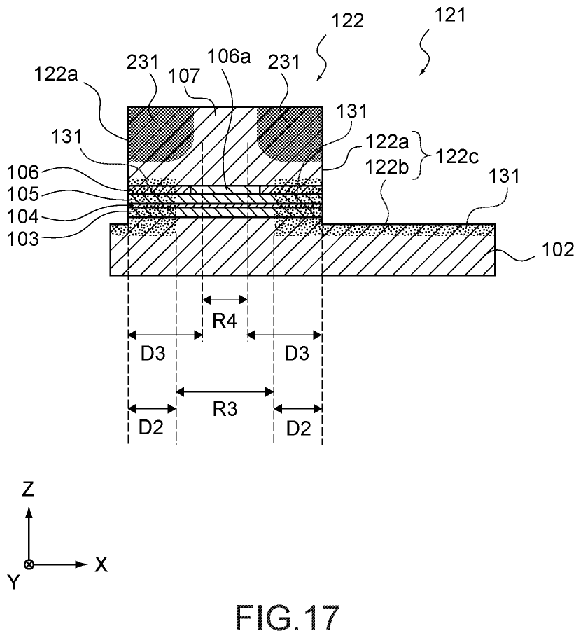

The ion implantation region 131 is a region insulated by implanting ions into the material of the semiconductor stacked body 121, similarly to the first embodiment. As shown in FIG. 16 to FIG. 18, the ion implantation region 131 is formed to reach a predetermined depth of the n-side spacer layer 103, the active layer 104, the p-side spacer layer 105, and the confinement layer 106 from the outer peripheral surface 122a of the mesa 122, i.e., formed in an annular shape on the outer periphery portion of these layers. In FIG. 17 and FIG. 18, a depth from the outer peripheral surface 122a of the ion implantation region 131 is shown as the depth D2.

The depth D2 is a depth shallower than the depth D1 (see FIG. 3) that is the depth of the oxidized region 106b from the outer peripheral surface 122a, and does not reach the non-oxidized region 106a. For this reason, the ion implantation region 131 provided in the confinement layer 106 is separated from the non-oxidized region 106a. In FIG. 17 and FIG. 18, the inner diameter of the ion implantation region 131 is shown as the inner diameter R3.

Further, the ion implantation region 131 is formed also in part of the n-type mirror 102 on the side of the active layer 104 and in part of the p-type mirror 107 on the side of the active layer 104. As shown in FIG. 17, the ion implantation region 131 can be exposed on the non-outer peripheral surface 122b and can be formed to reach a certain depth from the non-outer peripheral surface 122b.

The ion species of ions to be implanted into the ion implantation region 131 can be H, C, B, O, Ar, Al, Ga, or As. Of these, an H ion (proton) is suitable because it has the smallest atomic radius and is easy to implant deeply. The implantation amount (dose amount) of the ion is suitably 5×10¹⁴ ions/cm² or more in the case of H, and is suitably 5×10¹³ ions/cm² or more in the case of another ion species.

Here, the concentration distribution of the ion species in the ion implantation region 131 differs depending on the number of ion implantation stages. In the case where the ion implantation region 131 is formed by one-stage implantation of ions, the concentration distribution of the ion species in the direction (Z direction) perpendicular to a layer surface direction has only one peak. Meanwhile, in the case where the ion implantation region 131 is formed by multi-stage implantation of ions, the concentration distribution of the ion species in the direction (Z direction) perpendicular to a layer surface direction has many peaks.

Note that the ion implantation region 131 does not need to be provided in all the respective layers and only needs to be provided in at least the active layer 104 and the confinement layer 106.

The impurity diffusion region 231 is a region obtained by diffusing an impurity in the material of the semiconductor stacked body 121. The impurity can be diffused by thermal diffusion. As shown in FIG. 16 to FIG. 18, the impurity diffusion region 231 is formed to reach a predetermined depth of the p-type mirror 107 from the outer peripheral surface 122a of the mesa 122 and is formed in an annular shape on the outer periphery portion of the p-type mirror 107. In FIG. 17 and FIG. 18, the depth of the impurity diffusion region 231 from the outer peripheral surface 122a is shown as a depth D3.

The depth D3 is a depth deeper than the depth D2 that is the depth of the ion implantation region 131 from the outer peripheral surface 122a. Further, the depth D3 may be deeper or shallower than the depth D1 that is the depth of the oxidized region 106b from the outer peripheral surface 122a but is suitably similar to the depth D1. In FIG. 17 and FIG. 18, the inner diameter of the impurity diffusion region 231 is shown as an inner diameter R4.

FIG. 19 is a schematic diagram showing the distribution of the ion implantation region 131 and the impurity diffusion region 231 in the layer surface direction (X-Y direction), and is a diagram when the mesa 122 is viewed from the direction (Z direction) perpendicular to the layer surface direction. In the figure, the ion implantation region 131 is a region with dots and the impurity diffusion region 231 is a region with diagonal lines. As shown in the figure, the impurity diffusion region 231 is provided in a range that overlaps with the ion implantation region 131 when the mesa 122 is viewed from the Z direction.

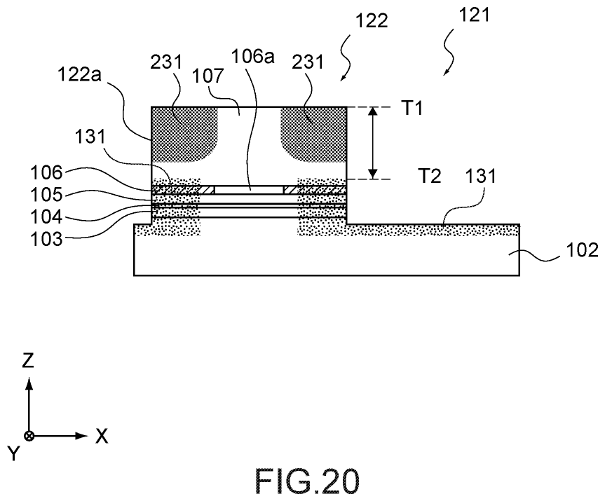

FIG. 20 is a schematic diagram showing the distribution of the impurity diffusion region 231 in the stacking direction (Z direction). As shown in the figure, the impurity diffusion region 231 is distributed from a surface T1 to an interface T2, the surface T1 being a surface of the mesa 122 parallel to the layer surface direction (X-Y direction), the interface T2 being an interface closest to the surface T1, of the interfaces of the ion implantation region 131. The impurity diffusion region 231 is exposed on the surface T1, may be separated from the interface T2 as shown in FIG. 20 and may be adjacent to the interface T2. Note that the interface T2 can be a plane having the impurity concentration larger than 1×10⁺¹⁸/cm³ by ion implantation.

Although the p-electrode 110 is formed on the surface T1, the impurity diffusion region 231 is exposed on the surface T1 and the p-electrode 110 abuts on the impurity diffusion region 231. Therefore, the impurity diffusion region 231 has been formed to reach a predetermined depth from the outer peripheral surface 122a between the p-electrode 110 and the ion implantation region 131.

The impurity forming the impurity diffusion region 231 can be C, Zn, or Mg, and the concentration thereof is suitably 1×10¹⁷/cm³ or more. Further, although the impurity diffusion region 231 is provided in the p-type mirror 107 in this embodiment, in the case where another semiconductor layer different from the p-type mirror 107 is provided between the p-electrode 110 and the ion implantation region 131, the impurity diffusion region 231 can be provided also in the semiconductor layer.

The VCSEL element 200 has the configuration described above. Note that in the VCSEL element 200, the n-type and the p-type may be reversed. In this case, although the impurity diffusion region 213 is provided in the n-type mirror, the impurity forming the impurity diffusion region 231 can be Si, S, or Se. Also in this case, the impurity concentration is suitably 1×10¹⁷/cm³ or more.

[Operation of VCSEL Element]

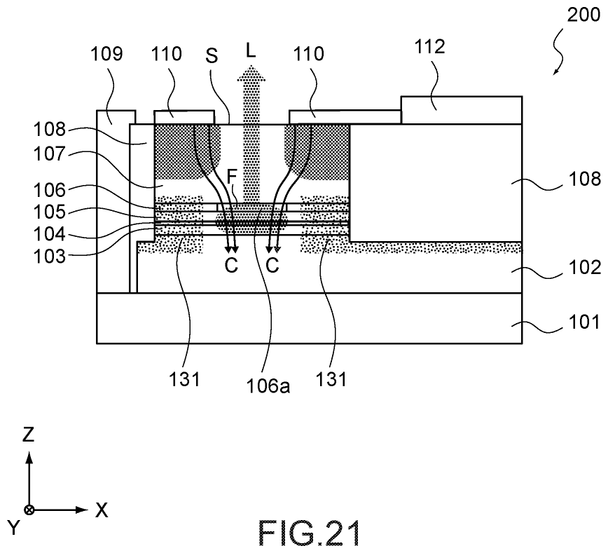

An operation of the VCSEL element 200 will be described. FIG. 21 is a schematic diagram showing an operation of the VCSEL element 200. The VCSEL element 200 operates in a way similar to that of the VCSEL element 100 according to the first embodiment. That is, when a voltage is applied between the n-electrode 109 and the p-electrode 110, a current is injected into the non-oxidized region 106a as shown by the arrows C in FIG. 21.

This injected current causes the spontaneously emitted light F, and the spontaneously emitted light F is reflected by the n-type mirror 102 and the p-type mirror 107. The n-type mirror 102 and the p-type mirror 107 are configured to reflect light having the oscillation wavelength λ, and the laser beam L generated by laser oscillation is emitted from the light-emitting surface S.

Here, in the VCSEL element 200, by providing the ion implantation region 131, it is possible to prevent a current from passing through the outer peripheral region of the mesa 122, reduce the junction capacitance in the outer peripheral region of the mesa 122, and improve the electrical band of the VCSEL element 200, similarly to the first embodiment. Further, in the VCSEL element 200, by providing the impurity diffusion region 231, it is possible to reduce the electrical resistance between the p-electrode 110 and the non-oxidized region 106a as described below.

[Method of Producing VCSEL Element]

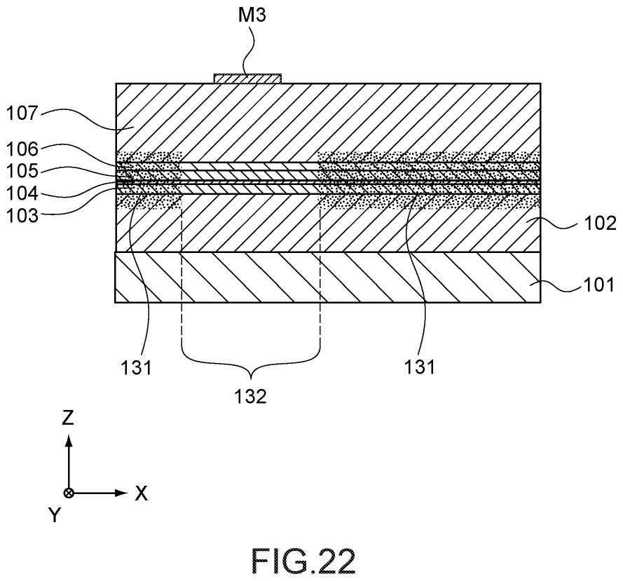

A method of producing the VCSEL element 100 will be described. FIG. 22 to FIG. 24 are each a schematic diagram showing a method of producing the VCSEL element 200.

Similarly to the first embodiment, the respective layers are stacked on the substrate 101 (see FIG. 11), and the mask M1 using a resist or the like is formed on the p-type mirror 107 (see FIG. 12). Ions are implanted from above this mask M1 using an ion implanter to form the ion implantation region 131. A region into which ions have not been implanted due to the mask M1 is defined as the non-implantation region 132. The depth of ion implantation in the ion implantation region 131 is within a range in which at least the active layer 104 and the confinement layer 106 are included in the ion implantation region 131 in the depth direction (Z direction).

The range of the ion implantation region 131 in the depth direction (Z direction) can be adjusted by the acceleration voltage at the time of ion implantation, and the ion concentration can be adjusted by the dose amount at the time of ion implantation. In the case where the ion implantation region 131 can be implanted in a necessary range by one time of ion implantation, ions are implanted by one-stage implantation with a constant acceleration voltage. In the case where the ion implantation region 131 cannot be formed in a necessary range by one time of ion implantation, ions are implanted by multi-stage ion implantation.

After that, the mask M1 is peeled off, and a mask M3 is formed on the p-type mirror 107 as shown in FIG. 22. The mask M3 can be, for example, a dielectric material film such as SiO₂. In the mask M3, an opening is provided such that a region through which ions have passed in the ion implantation step described above is exposed on the surface of the p-type mirror 107.

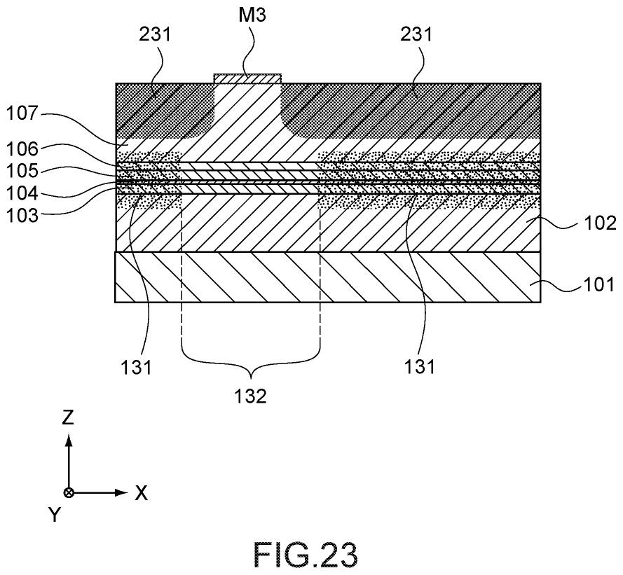

Further, as shown in FIG. 23, an impurity is diffused using the mask M3 to form the impurity diffusion region 231. The impurity can be diffused by thermal diffusion, and thermal diffusion in the gas phase containing impurity components and solid-phase thermal diffusion in which a solid containing impurity components is caused to abut and heated can be used. In the thermal diffusion, the depth of impurity diffusion can be adjusted by the heating temperature and heating time such that the impurity diffusion region 231 does not exceed the interface T2 (see FIG. 20) of the ion implantation region 131.

Specifically, in the case where the impurity to be diffused is Zn, examples of the gas phase containing impurity components include diethyl zinc and dimethyl zinc and examples of the solid containing impurity components include ZnO. Further, in the case where the impurity to be diffused is C, examples of the gas phase containing impurity components include CBr₄ (carbon tetrabromide) and examples of the solid containing impurity components include a carbon film. In the case where the impurity to be diffused is Mg, examples of the gas phase containing impurity components include Cp₂Mg (cyclopentadienyl magnesium) and examples of the solid containing impurity components include an MgO film.

Note that the impurity diffusion region 231 can be formed by diffusing an impurity by a method other than thermal diffusion. For example, the impurity diffusion region 231 can be formed by ion implantation.

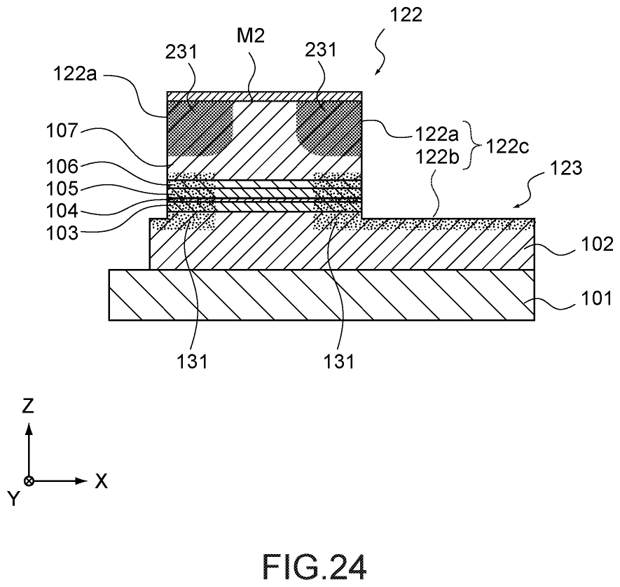

After that, the mask M3 is peeled off, and the mask M2 is formed on the p-type mirror 107 as shown in FIG. 24. Further, the p-type mirror 107, the confinement layer 106, the p-side spacer layer 105, the active layer 104, the n-side spacer layer 103, and the n-type mirror 102 are removed by etching using the mask M2. The etching can be, for example, dry etching.

By this etching, the pillar-shaped mesa 122 having the non-implantation region 132 is formed, and the removal surface 122c including the outer peripheral surface 122a and the non-outer peripheral surface 122b is formed. End surfaces of the respective layers including the active layer 104 and the confinement layer 106 are exposed on the outer peripheral surface 122a. At this time, the depth D2 (see FIG. 17) of the ion implantation region 131 and the depth D3 (see FIG. 17) of the impurity diffusion region 231 from the outer peripheral surface 122a can be defined by the size of the mask M2. Further, the etching depth (Z direction) is suitably within the depth range of the ion implantation region 131 in the n-type mirror 102. As a result, the ion implantation region 131 provided in the n-type mirror 102 is exposed on the non-outer peripheral surface 122b.

Further, this stacked body is heated in water vapor to oxidize the confinement layer 106 from the outer periphery side. As a result, the oxidized region 106b is formed in the outer periphery portion of the confinement layer 106, and the non-oxidized region 106a is formed on the central part of the confinement layer 106. At this time, the oxidization condition is adjusted such that the depth D1 of the oxidized region 106b from the outer peripheral surface 122a is deeper than the depth D2 (see FIG. 9). As a result, the inner diameter R1 of the oxidized region 106b is smaller than the inner diameter R3 of the ion implantation region 131, and the non-oxidized region 106a is formed to be separated from the ion implantation region 131.

After that, the insulator 108 is embedded in the recessed portion 123, and the n-electrode 109, the p-electrode 110, the n-electrode pad 111, and the p-electrode pad 112 are formed, whereby the VCSEL element 200 can be produced.

In this production method, since the ion implantation region 131 and the impurity diffusion region 231 can be formed by adding a several-stage step (mask formation/ion implantation/impurity diffusion/mask peeling) necessary for ion implantation and impurity diffusion, it is substantially unnecessary to change the production process. Further, since the number of states for implanting ions is small, it is possible to significantly reduce the process time.

Further, since the change in quality of the mask M1 due to ion implantation can be minimized, it is possible to avoid the remaining of the mask M1 and an additional peeling step associated therewith. Further, since the ion implantation region 131 is formed in the vicinity of the end surface of the active layer 104 and insulated, carriers are shielded from the damaged layer, which prevents the reliability from decreasing. Further, it is possible to stabilize the etching processing surface by insulating the non-outer peripheral surface 122b by the ion implantation region 131.

[Effects of VCSEL Element]

In the VCSEL element 200, similarly to the first embodiment, the refractive index decreases due to oxidization in the oxidized region 106b formed in the confinement layer 106, and a region having a low refractive index is formed around the light-emitting portion. As a result, three-dimensionally high light confinement in the active layer 104 is realized together with the optical resonator structure by the n-type mirror 102 and the p-type mirror 107. When the light confinement is improved, since the ratio of light that receives a stimulated emission gain in the active layer 104 increases and the effective light gain has a high value, it is possible to make the time responsiveness of light high.

Further, in the VCSEL element 200, by providing the ion implantation region 131, it is possible to prevent a current from passing through the outer peripheral region of the mesa 122 and reduce the junction capacitance in the outer peripheral region of the mesa 122. As a result, it is possible to improve the electric time responsiveness of the VCSEL element 200. As described above, in the VCSEL element 200, it is possible to improve both the time responsiveness of light and electric time responsiveness and realize high-speed modulation.

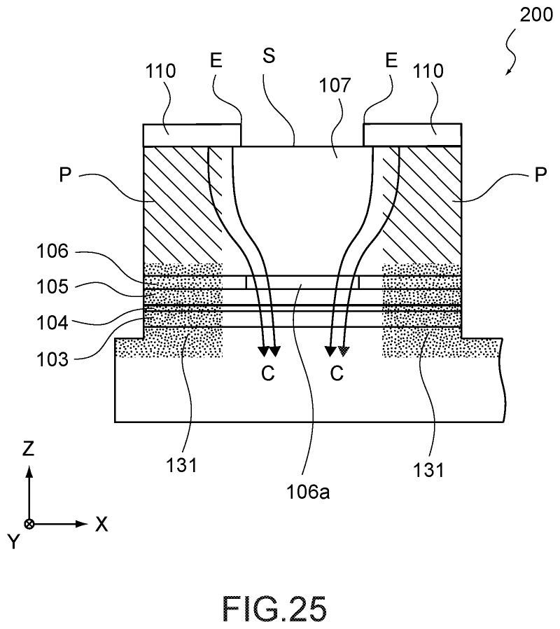

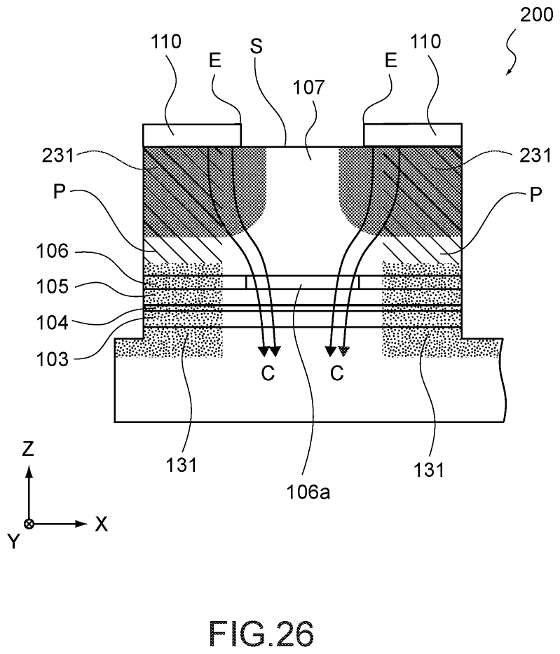

Further, in the VCSEL element 200, by providing the impurity diffusion region 231, the following effects can be achieved. FIG. 25 and FIG. 26 are each a schematic diagram showing the effects of the impurity diffusion region 231. As shown in FIG. 25, an ion passage region P is formed on the upper layer of the ion implantation region 131. The ion passage region P is a region through which ions have passed in the ion implantation step and the crystal structure of the p-type mirror 107 is damaged by the passage of ions.

For this reason, the ion passage region P has large electrical resistance and there is a possibility that currents flowing from the p-electrode 110 to the p-type mirror 107 (arrows C in the figure) are concentrated in the vicinity of a peripheral edge E inside the p-electrode 110. In this case, the electrical resistance of the entire element increases.

Here, in the VCSEL element 200, as shown in FIG. 26, the impurity diffusion region 231 is provided so as to overlap with the ion passage region P between the p-electrode 110 and the ion implantation region 131. In the impurity diffusion region 231, the damage of the crystal structure is repaired by the diffusion of the impurity and the electrical resistance is reduced. As a result, a current is not concentrated in the peripheral edge E inside the p-electrode 110 and it is possible to reduce the electrical resistance of the entire element.

Therefore, in the VCSEL element 200, it is possible to improve both the time responsiveness of light and electric time responsiveness, improve the electrical properties, and improve the electrical band by reducing the resistance of the element.

[Regarding Photoelectric Conversion Apparatus]

The VCSEL element 200 can be used as a light-emitting element in a photoelectric conversion apparatus for communication. Since the VCSEL element 200 is capable of performing high-speed modulation and has high reliability as described above, it is suitable for use in ultra-high-speed optical communication such as a communication speed of 50 Gbps.

Note that the present technology may also take the following configurations.

(1) A vertical cavity surface emitting laser element, including:
a semiconductor stacked body that includes
   a first mirror having a first conductive type,
   a second mirror that has a second conductive type and causes optical resonance together with the first mirror,
   an active layer provided between the first mirror and the second mirror, and
   a confinement layer that is provided between the first mirror and the second mirror and has a non-oxidized region and an oxidized region, the non-oxidized region being formed of a conductive material, the oxidized region being provided around the non-oxidized region and being formed of an insulating material obtained by oxidizing the conductive material, and has
   a mesa having an outer peripheral surface from which end surfaces of the active layer and the confinement layer are exposed and
   an ion implantation region that is a region into which ions have been implanted, is formed to reach a predetermined depth in the active layer and the confinement layer from the outer peripheral surface, and is separated from the non-oxidized region.

(2) The vertical cavity surface emitting laser element according to (1) above, in which
the mesa is formed by partial removable of the semiconductor stacked body, and
the ion implantation region is exposed on a removal surface formed by the partial removable of the semiconductor stacked body.

(3) The vertical cavity surface emitting laser element according to (2) above, further including
an insulator that is provided around the mesa and covers the removal surface.

(4) The vertical cavity surface emitting laser element according to any one of (1) to (3) above, in which
the ion implantation region has one peak of concentration distribution of an ion species of the ions in a direction perpendicular to a layer surface direction.

(5) The vertical cavity surface emitting laser element according to any one of (1) to (4) above, in which
the ion species is H, and
an implantation amount of the ion species is 5×10¹⁴ ions/cm² or more.

(6) The vertical cavity surface emitting laser element according to any one of (1) to (4) above, in which
the ion species is C, B, O, Ar, Al, Ga, or As, and
an implantation amount of the ion species is 5×10¹³ ions/cm² or more.

(7) The vertical cavity surface emitting laser element according to any one of (1) to (6) above, in which
the mesa has a surface parallel to a layer surface direction,
the vertical cavity surface emitting laser element further including an electrode formed on the surface, in which
the semiconductor stacked body further has an impurity diffusion region formed to reach a predetermined depth from the outer peripheral surface between the electrode and the ion implantation region, an impurity being diffused in the impurity diffusion region.

(8) The vertical cavity surface emitting laser element according to (7) above, in which
the impurity diffusion region is a region in which the impurity is thermally diffused.

(9) The vertical cavity surface emitting laser element according to (7) or (8) above, in which
the impurity diffusion region may be provided in a range that overlaps with the ion implantation region when the mesa is viewed from a direction perpendicular to the layer surface direction.

(10) The vertical cavity surface emitting laser element according to any one of (7) to (9) above, in which
the impurity diffusion region has a concentration of the impurity of 1×10¹⁷/cm³ or more.

(11) The vertical cavity surface emitting laser element according to any one of (7) to (10) above, in which
the impurity diffusion region is provided in the first mirror,
the first conductive type is a p-type, and
the impurity is C, Zn, or Mg.

(12) The vertical cavity surface emitting laser element according to any one of (7) to (9) above, in which
the impurity diffusion region is provided in the first mirror,
the first conductive type is an n-type, and
the impurity is Si, S, or Se.

(13) A method of producing a vertical cavity surface emitting laser element, including:
forming a semiconductor stacked body that includes a first mirror having a first conductive type, a second mirror that has a second conductive type and causes optical resonance together with the first mirror, an active layer provided between the first mirror and the second mirror, and a confinement layer provided between the first mirror and the second mirror;
implanting, in the semiconductor stacked body, ions from a direction perpendicular to a layer surface direction excluding a non-implantation region to form an ion implantation region;
etching the semiconductor stacked body to form a mesa that has the non-implantation region and an outer peripheral surface from which end surfaces of the active layer and the confinement layer are exposed, the ion implantation region being distributed from the outer peripheral surface to a first depth in the active layer and the confinement layer; and
oxidizing the confinement layer from the outer peripheral surface to form an oxidized region from the outer peripheral surface to a second depth deeper than the first depth in the confinement layer.

(14) The method of producing a vertical cavity surface emitting laser element according to (13) above, further including
a step of diffusing an impurity in the semiconductor stacked body to form an impurity diffusion region.

(15) The method of producing a vertical cavity surface emitting laser element according to (14) above, in which
the step of forming an impurity diffusion region is performed after the step of forming an ion implantation region and before the step of forming a mesa, and the impurity is diffused in a region through which the ions have passed in the step of forming an ion implantation region.

(16) The method of producing a vertical cavity surface emitting laser element according to (14) or (15) above, in which
the step of forming an impurity diffusion region includes diffusing the impurity by thermal diffusion.

(17) A photoelectric conversion apparatus, including:
a vertical cavity surface emitting laser element that includes
   a semiconductor stacked body that includes a first mirror having a first conductive type, a second mirror that has a second conductive type and causes optical resonance together with the first mirror, an active layer provided between the first mirror and the second mirror, and a confinement layer that is provided between the first mirror and the second mirror and has a non-oxidized region and an oxidized region, the non-oxidized region being formed of a conductive material, the oxidized region being provided around the non-oxidized region and being formed of an insulating material obtained by oxidizing the conductive material, and has a mesa having an outer peripheral surface from which end surfaces of the active layer and the confinement layer are exposed and an ion implantation region that is a region into which ions have been implanted, is formed to reach a predetermined depth in the active layer and the confinement layer from the outer peripheral surface, and is separated from the non-oxidized region.

(18) The photoelectric conversion apparatus according to (17) above, in which
the mesa has a surface parallel to a layer surface direction,
the vertical cavity surface emitting laser element further including an electrode formed on the surface, in which
the semiconductor stacked body further has an impurity diffusion region formed to reach a predetermined depth from the outer peripheral surface between the electrode and the ion implantation region, an impurity being diffused in the impurity diffusion region.

### REFERENCE SIGNS LIST

100, 200 VCSEL element
101 substrate
102 n-type mirror
103 n-side spacer layer
104 active layer
105 p-side spacer layer
106 confinement layer
106a non-oxidized region
106b oxidized region
107 p-type mirror
108 insulator
109 n-electrode
110 p-electrode
111 n-electrode pad
112 p-electrode pad
121 semiconductor stacked body
122 mesa
122a outer peripheral surface
122b non-outer peripheral surface
122c removal surface
123 recessed portion
131 ion implantation region
132 non-implantation region
231 impurity diffusion region

1. A vertical cavity surface emitting laser element, comprising:
a semiconductor stacked body that includes
a first mirror having a first conductive type,
a second mirror that has a second conductive type and causes optical resonance together with the first mirror,
an active layer provided between the first mirror and the second mirror, and
a confinement layer that is provided between the first mirror and the second mirror and has a non-oxidized region and an oxidized region, the non-oxidized region being formed of a conductive material, the oxidized region being provided around the non-oxidized region and being formed of an insulating material obtained by oxidizing the conductive material, and has
a mesa having an outer peripheral surface from which end surfaces of the active layer and the confinement layer are exposed and
an ion implantation region that is a region into which ions have been implanted, is formed to reach a predetermined depth in the active layer and the confinement layer from the outer peripheral surface, and is separated from the non-oxidized region.

2. The vertical cavity surface emitting laser element according to claim 1, wherein
the mesa is formed by partial removable of the semiconductor stacked body, and
the ion implantation region is exposed on a removal surface formed by the partial removable of the semiconductor stacked body.

3. The vertical cavity surface emitting laser element according to claim 2, further comprising
an insulator that is provided around the mesa and covers the removal surface.

4. The vertical cavity surface emitting laser element according to claim 1, wherein
the ion implantation region has one peak of concentration distribution of an ion species of the ions in a direction perpendicular to a layer surface direction.

5. The vertical cavity surface emitting laser element according to claim 1, wherein
the ion species is H, and
an implantation amount of the ion species is 5×10¹⁴ ions/cm² or more.

6. The vertical cavity surface emitting laser element according to claim 1, wherein
the ion species is C, B, O, Ar, Al, Ga, or As, and
an implantation amount of the ion species is 5×10¹³ ions/cm² or more.

7. The vertical cavity surface emitting laser element according to claim 1, wherein
the mesa has a surface parallel to a layer surface direction,
the vertical cavity surface emitting laser element further comprising an electrode formed on the surface, wherein
the semiconductor stacked body further has an impurity diffusion region formed to reach a predetermined depth from the outer peripheral surface between the electrode and the ion implantation region, an impurity being diffused in the impurity diffusion region.

8. The vertical cavity surface emitting laser element according to claim 7, wherein
the impurity diffusion region is a region in which the impurity is thermally diffused.

9. The vertical cavity surface emitting laser element according to claim 7, wherein
the impurity diffusion region may be provided in a range that overlaps with the ion implantation region when the mesa is viewed from a direction perpendicular to the layer surface direction.

10. The vertical cavity surface emitting laser element according to claim 7, wherein
the impurity diffusion region has a concentration of the impurity of 1×10¹⁷/cm³ or more.

11. The vertical cavity surface emitting laser element according to claim 7, wherein
the impurity diffusion region is provided in the first mirror,
the first conductive type is a p-type, and
the impurity is C, Zn, or Mg.

12. The vertical cavity surface emitting laser element according to claim 7, wherein
the impurity diffusion region is provided in the first mirror,
the first conductive type is an n-type, and
the impurity is Si, S, or Se.

13. A method of producing a vertical cavity surface emitting laser element, comprising:
forming a semiconductor stacked body that includes a first mirror having a first conductive type, a second mirror that has a second conductive type and causes optical resonance together with the first mirror, an active layer provided between the first mirror and the second mirror, and a confinement layer provided between the first mirror and the second mirror;
implanting, in the semiconductor stacked body, ions from a direction perpendicular to a layer surface direction excluding a non-implantation region to form an ion implantation region;
etching the semiconductor stacked body to form a mesa that has the non-implantation region and an outer peripheral surface from which end surfaces of the active layer and the confinement layer are exposed, the ion implantation region being distributed from the outer peripheral surface to a first depth in the active layer and the confinement layer; and
oxidizing the confinement layer from the outer peripheral surface to form an oxidized region from the outer peripheral surface to a second depth deeper than the first depth in the confinement layer.

14. The method of producing a vertical cavity surface emitting laser element according to claim 13, further comprising
a step of diffusing an impurity in the semiconductor stacked body to form an impurity diffusion region.

15. The method of producing a vertical cavity surface emitting laser element according to claim 14, wherein
the step of forming an impurity diffusion region is performed after the step of forming an ion implantation region and before the step of forming a mesa, and the impurity is diffused in a region through which the ions have passed in the step of forming an ion implantation region.

16. The method of producing a vertical cavity surface emitting laser element according to claim 14, wherein
the step of forming an impurity diffusion region includes diffusing the impurity by thermal diffusion.

17. A photoelectric conversion apparatus, comprising:
a vertical cavity surface emitting laser element that includes
a semiconductor stacked body that includes a first mirror having a first conductive type, a second mirror that has a second conductive type and causes optical resonance together with the first mirror, an active layer provided between the first mirror and the second mirror, and a confinement layer that is provided between the first mirror and the second mirror and has a non-oxidized region and an oxidized region, the non-oxidized region being formed of a conductive material, the oxidized region being provided around the non-oxidized region and being formed of an insulating material obtained by oxidizing the conductive material, and has a mesa having an outer peripheral surface from which end surfaces of the active layer and the confinement layer are exposed and an ion implantation region that is a region into which ions have been implanted, is formed to reach a predetermined depth in the active layer and the confinement layer from the outer peripheral surface, and is separated from the non-oxidized region.

18. The photoelectric conversion apparatus according to claim 17, wherein
the mesa has a surface parallel to a layer surface direction,
the vertical cavity surface emitting laser element further comprising an electrode formed on the surface, wherein
the semiconductor stacked body further has an impurity diffusion region formed to reach a predetermined depth from the outer peripheral surface between the electrode and the ion implantation region, an impurity being diffused in the impurity diffusion region.
